(19) United States
(12) Patent Application Publication
(10) Pub. No.: US 2009/0086456 A1
(43) Pub. Date: Apr. 2, 2009

(54) TOOL-LESS BLADE EJECTOR LATCH WITH INTEGRATED SPRING

(75) Inventors: Michael T. Milo, Los Altos, CA (US); Mark H. Chen, Palo Alto, CA (US); Brett C. Ong, San Jose, CA (US); Daniel Hruska, San Carlos, CA (US)

Correspondence Address: OSHA LIANG L.L.P./SUN, TWO HOUSTON CENTER, 909 FANNIN, SUITE 3500, HOUSTON, TX, 77010, US

(73) Assignee: Sun Microsystems, Inc., Santa Clara, CA (US)

(21) Appl. No.: 11/863,011

(22) Filed: Sep. 27, 2007

(51) Int. Cl. H05K 7/16

(52) U.S. Cl. 361/801

(57) ABSTRACT

An ejector latch for removing a blade module from a server chassis includes a latch lever, an ejector catch, and an ejector pull part. The latch lever includes a pivot hole near a first end thereof operable to be coupled to the blade module and a bend near a second end thereof. The ejector catch includes a through-hole passing therethrough and a hook operable to hook onto the server chassis. The ejector pull part includes an integrated spring operable to return the ejector pull part to an original position after being pulled. The second end of the latch lever passes through the through-hole of the ejector catch. The ejector pull part is disposed on the bend near the second end of the latch lever and inside the through-hole of the ejector catch such that, when the ejector pull part is pulled, the ejector pull part slides along the bend near the second end of the latch lever and pushes on a wall of the through-hole to disengage the hook of the ejector catch from the server chassis.

### BACKGROUND OF INVENTION

1. Field of the Invention

The invention generally relates to an ejector latch for ejecting a blade server module from a computer server chassis.

2. Background Art

A typical computer server rack is composed of a computer server chassis (“server chassis”) with a number of blade server modules (“blade modules”) disposed therein.

One or more hard drives are disposed within each blade module. The blade modules can be removed from the server chassis by disengaging the blade module from the server chassis. Important considerations in designing disengagement mechanisms include cost, reliability, and operability.

### SUMMARY OF INVENTION

In one or more embodiments of the present invention, an ejector latch for removing a blade module from a server chassis comprising: a latch lever comprising a pivot hole near a first end thereof operable to be coupled to the blade module and a bend near a second end thereof; an ejector catch comprising a through-hole passing therethrough and a hook operable to hook onto the server chassis; and an ejector pull part comprising an integrated spring operable to return the ejector pull part to an original position after being pulled, wherein the second end of the latch lever passes through the through-hole of the ejector catch, wherein the ejector pull part is disposed on the bend near the second end of the latch lever and inside the through-hole of the ejector catch such that, when the ejector pull part is pulled, the ejector pull part slides along the bend near the second end of the latch lever and pushes on a wall of the through-hole to disengage the hook of the ejector catch from the server chassis.

Other aspects and advantages of the invention will be apparent from the following description and the appended claims.

### BRIEF DESCRIPTION OF DRAWINGS

FIG. 1 shows computer server rack composed of a server chassis with blade modules disposed therein, having an ejector latch according to one or more embodiments of the present invention.

FIGS. 2(a) and 2(b) show exploded perspective views of an ejector latch according to one or more embodiments of the present invention.

FIGS. 3(a) and 3(b) show side views of an ejector latch according to one or more embodiments of the present invention.

FIG. 4 shows a top view of an ejector latch according to one or more embodiments of the present invention.

FIGS. 5(a) and 5(b) show side views of a first ejector pull part of an ejector latch according to one or more embodiments of the present invention.

FIGS. 6(a)-6(d) show the removal of the blade module from the server chassis using an ejector latch according to one or more embodiments of the present invention.

### DETAILED DESCRIPTION

Exemplary embodiments of the invention will be described with reference to the accompanying figures. Like items in the figures are shown with the same reference numbers.

In embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid obscuring the invention.

Embodiments of the invention relate to an ejector latch for ejecting a blade module from a server chassis. More specifically, one or more embodiments of the invention relate to a tool-less blade module ejector latch with an integrated spring.

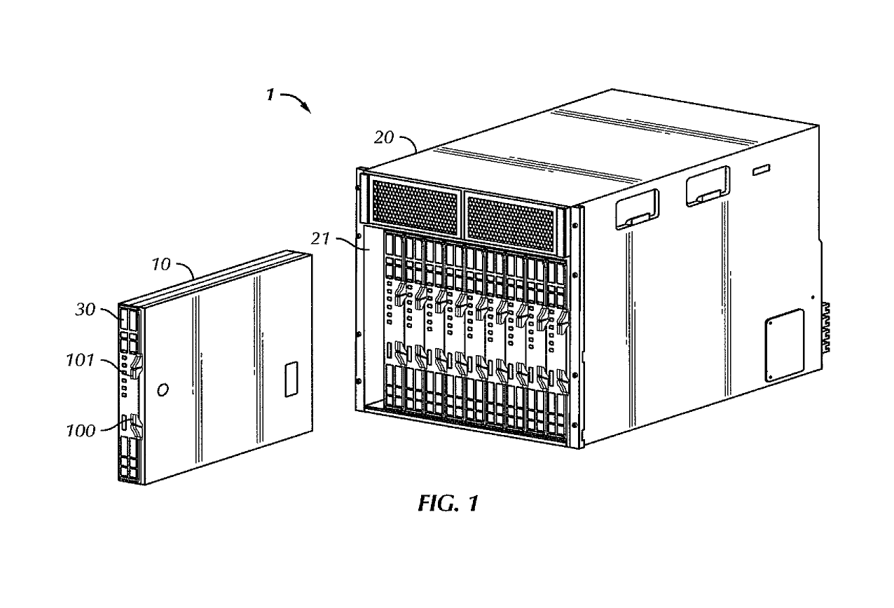

FIG. 1 shows a perspective view of a computer server rack 1. The computer server rack I has a server chassis 20 with blade modules 10 disposed in slots 21 formed therein. One or more hard drives 30 are disposed in each blade module 10. Ejector latches 100, 101 according to one or more embodiments of the present invention are disposed on the blade modules 10.

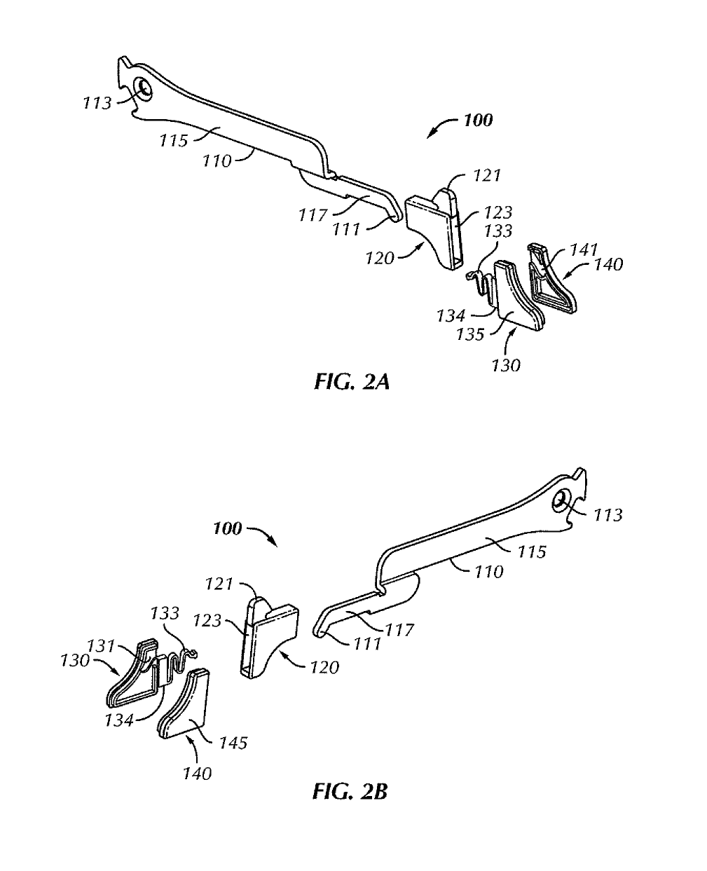

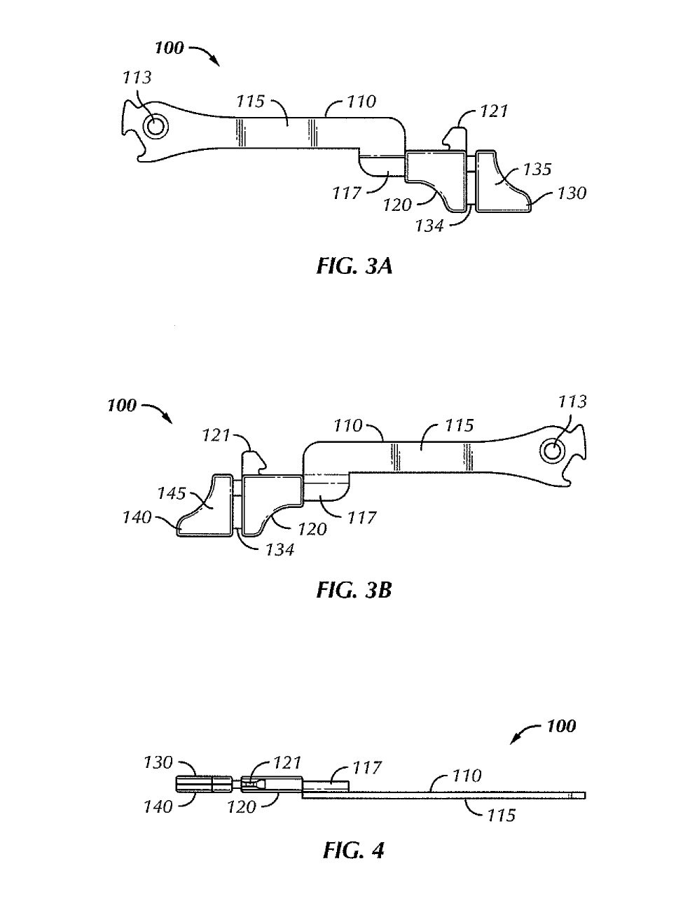

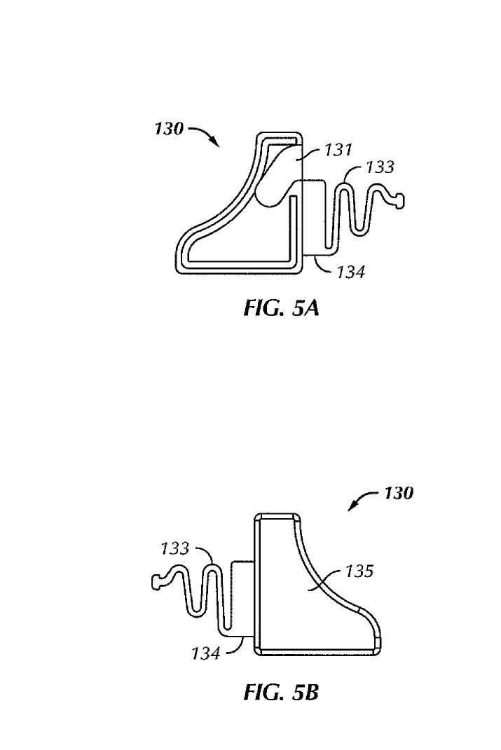

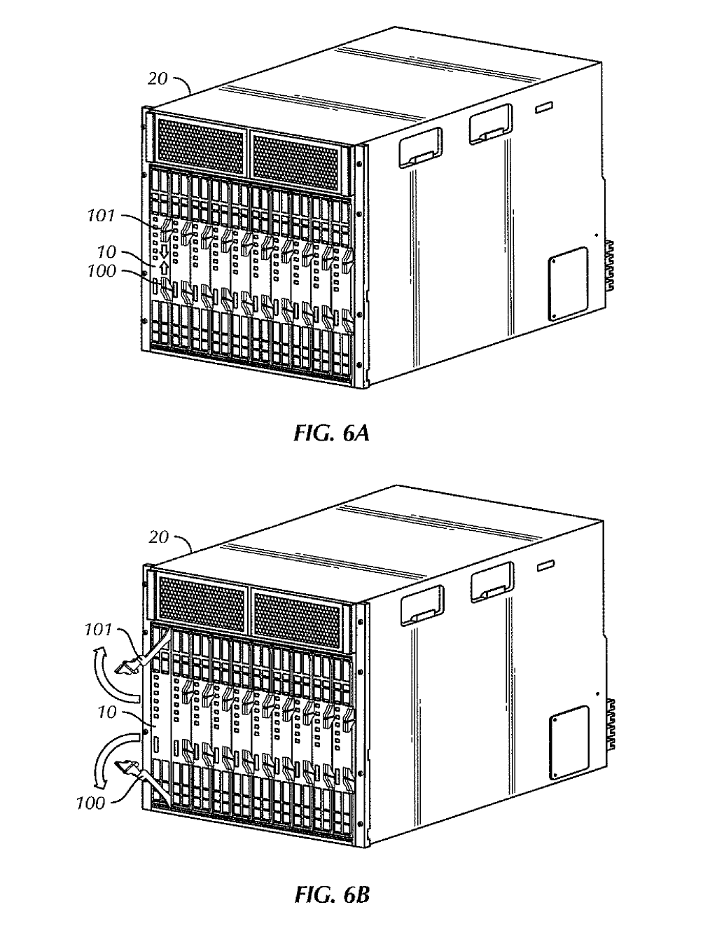

FIGS. 2(a) and 2(b) show exploded perspective views, FIGS. 3(a) and 3(b) show side views, and FIG. 4 shows a top view, of an ejector latch 100 according to one or more embodiments of the present invention. The ejector latch 100 includes a latch lever 110, ejector catch 120, first ejector pull part 130, and second ejector pull part 140. FIGS. 5(a) and 5(b) show side views of the first ejector pull part 130.

The latch lever 110 has lever portion 115 and an arm portion 117. As shown in FIG. 4, the lever portion 115 and the arm portion 117 are laterally offset, and as shown in FIGS. 3(a) and 3(b), are also vertically offset. A pivot hole 113 is formed on one end of the lever portion 115, and a bent end portion 111 is formed on one end of the arm portion 117.

The ejector catch 120 has a hook 121 on a flat top side, while the bottom side is curved. The ejector catch 120 has a through-hole 123 formed therein. The through-hole 123 is narrow on one side and broader on the other side, which facilitates operation of the ejector latch.

The first ejector pull part 130 and the second ejector pull part 140 have guide portions 131, 141 having a shape corresponding to the shape of the bent end portion 111 of the latch lever 110. The first ejector pull part 130 and the second ejector pull part 140 also have flat side areas 135, 145, which facilitates gripping by the user. The first ejector pull part 130 also has an integrated spring 133 protruding from an end thereof. Between the integrated spring 133 and the main body of the first ejector pull part 130 is a thick spring base 134. Although here, the integrated spring 133 is on the first ejector pull part 130, the integrated spring could also be disposed on the second ejector pull part 140, or both ejector pull parts 130, 140.

In assembling the ejector latch 100, the arm portion 117 is inserted into the narrow end of the though-hole 123 of the ejector catch 120, such that the bent end portion 111 protrudes past the broader end of the through-hole 123. The hook 121 on the ejector catch 120 faces the lever portion 115 of the latch lever 110. The integrated spring 133 of the first ejector pull part 130 is inserted into the broader end of the through-hole 123 of the ejector catch 120, under the arm portion 117 of the latch lever 110. The bottom of the integrated spring 133 and the spring base 134 abut against the curved bottom wall of the through-hole 123 in the ejector catch 120. The bent end portion 111 of the latch lever 110 is inserted into the guide portion 131 of the first ejector pull part 130. The second ejector pull part 140 is then brought together with the first ejector pull part 130 around the bent end portion 111 such that the bent end portion 111 fits into the guide portions 131, 141, and first ejector pull part 130 and the second ejector pull part 140 form the assembled ejector pull part. Although here, the ejector pull part is formed by two separate ejector pull parts 130, 140, it could also be formed as a single piece.

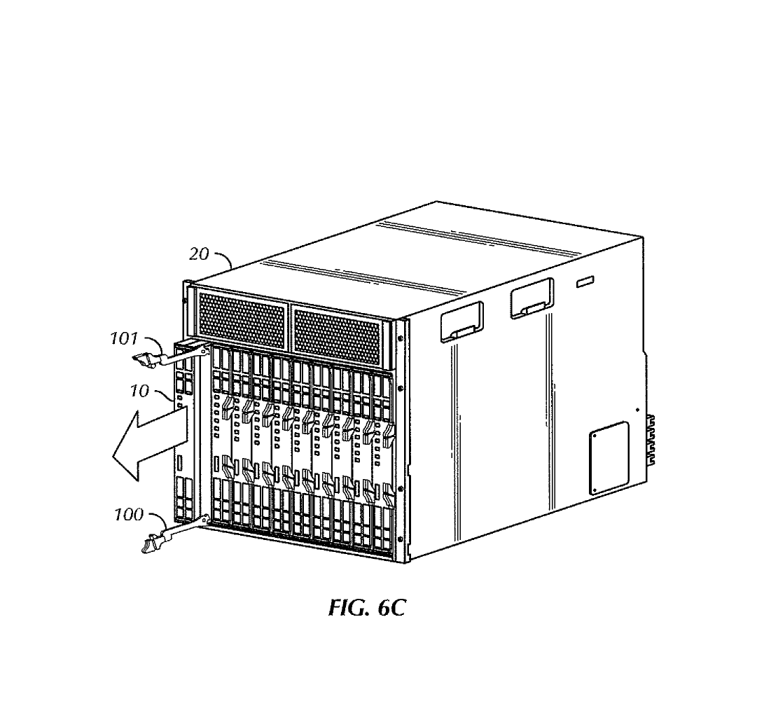

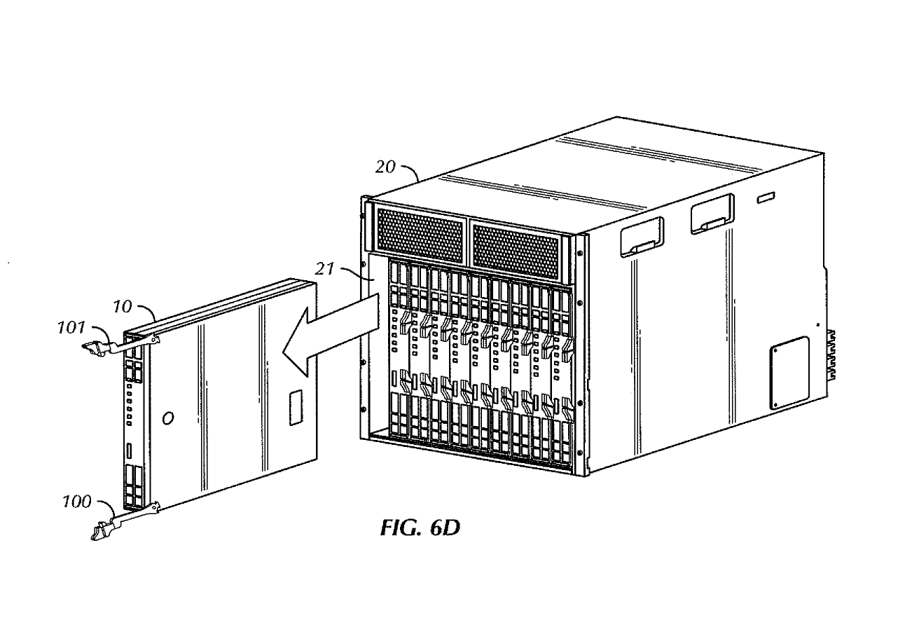

FIGS. 6(a)-6(d) show the removal of the blade module 10 from the server chassis 20 using an ejector latch according to one or more embodiments of the present invention.

The ejector latch 101 is a mirror image of the ejector latch 100, and works in the same manner as the ejector latch 100. Thus, explanation of the ejector latch 101 is hereby omitted. The ejector latch 100 is attached to the blade module 10 via the pivot hole 113, such that the ejector latch 100 can rotate about the pivot hole 113, by coupling the pivot hole to the blade module 10. The hook 121 on the ejector catch 120 hooks onto the server chassis 20 when inserted into a slot 21, locking the blade module 10 into the slot 21.

When a user grips side areas 135, 145 and pulls the ejector pull parts 130, 140 in the direction shown by the arrows in FIG. 6(a), the guide portions 131, 141 of the ejector pull parts 130, 140 are pulled away from the bent end portion 111 of the latch lever 110. The guide portions 131, 141 follow the bent end portion 111, and the ejector pull parts 130, 140 thus are forced diagonally downwards. Because the bottom of the integrated spring 133 and the spring base 134 abutted against the bottom wall of the though-hole 123 of the ejector catch 120, when the ejector pull parts 130, 140 thus are forced diagonally downwards, the integrated spring 133 and the spring base 134 push the ejector catch 120 downwards, unhooking the hook 121 from the server chassis 20, which unlocks the blade module 10 from the slot 21.

The ejector latch 100 is then rotated away from the blade module 10 about the pivot hole 113, as shown by the arrows in FIG. 6(b). Once the ejector latches 100, 101 are rotated about 90 degrees to become substantially perpendicular to the front surface of the blade module 10, the ejector latches 100, 101 are pulled in the direction shown in FIG. 6(c) to slide the blade module 10 out of the slot 21 of the server chassis 20. The user can then remove the entire blade module 10 from the slot 21, as shown in FIG. 6(d). In order to place the blade module 10 back into the server chassis 20, the blade module 10 is slid into the slot 21, and once the blade module 10 is as far back in the slot 21 as possible, the ejector latches 100, 101 are rotated back towards the blade module 10, opposite to the direction shown by the arrows in FIG. 6(b). Once the ejector latches 100, 101 are parallel to the front surface of the blade module 10, the hooks 121 on the ejector latches 100, 101 latch onto the server chassis, securing the blade module 10 the server chassis 20.

One or more embodiments of the present invention may have one or more of the following advantages. The need for an additional parts can be minimized, as the integrated spring 131 is formed as one piece with the first ejector pull part 130. This further decreases cost and increases reliability. An intuitive and ergonomic operation can be achieved because the ejector latch 100 serves as both the latch and the handle in removing the blade module 10. Part and assembly cost can be reduced, because of the tool-less assembly and the integrated spring 131.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. An ejector latch for removing a blade module from a server chassis comprising:
a latch lever comprising a pivot hole near a first end thereof operable to be coupled to the blade module and a bend near a second end thereof;
an ejector catch comprising a through-hole passing therethrough and a hook operable to hook onto the server chassis; and
an ejector pull part comprising an integrated spring operable to return the ejector pull part to an original position after being pulled,
wherein the second end of the latch lever passes through the through-hole of the ejector catch,
wherein the ejector pull part is disposed on the bend near the second end of the latch lever and inside the through-hole of the ejector catch such that, when the ejector pull part is pulled, the ejector pull part slides along the bend near the second end of the latch lever and pushes on a wall of the through-hole to disengage the hook of the ejector catch from the server chassis.

2. The ejector latch of claim 1, the latch lever further comprising a lever portion and an arm portion that are laterally and vertically offset from each other, wherein the pivot hole is disposed on the lever portion, and wherein the ejector catch and the ejector pull part are disposed on the arm portion.

3. The ejector latch of claim 1, wherein a guide portion corresponding to the bend near the second end of the latch lever is formed inside of the ejector pull part, and wherein the second end of the latch lever is disposed inside the guide portion.

4. The ejector latch of claim 1, wherein a surface of the ejector catch opposite a surface on which the hook is disposed is curved, and the integrated spring abuts against an inside surface of the ejector catch corresponding to the curved surface.

5. The ejector latch of claim 1 the ejector pull part further comprising a solid spring base that is abutted against the inside surface of the through-hole.

6. The ejector latch of claim 1, the ejector pull part further comprising a first ejector pull part piece and a second ejector pull part piece, wherein the first ejector pull part piece and a second ejector pull part piece are brought together to form the ejector pull part, and wherein the integrated spring is disposed on the first ejector pull part piece.

7. The ejector latch of claim 2, wherein the bend near the second end of the latch lever is on the arm portion of the latch lever.

8. The ejector latch of claim 7, wherein the arm portion after the bend closer to the second end of the latch lever is diagonal to the arm portion before the bend.

9. The ejector latch of claim 1, wherein the latch lever is operable to be rotated 90 degrees about the pivot hole.

10. The ejector latch of claim 1, wherein the latch lever is operable as a handle for pulling the blade module out of the server chassis

11. The ejector latch of claim 1, further comprising a second identical ejector latch disposed on the blade module.

12. The ejector latch of claim 1, wherein assembly of the latch requires no tools.
